(19) United States
(12) Patent Application Publication
(10) Pub. No.: US 2026/0050702 A1
(43) Pub. Date: Feb. 19, 2026

(54) DISCRETE-EVENT TRAVEL OPERATIONS WITH COLLISION AVOIDANCE AND DECELERATION

(71) Applicant: Autodesk, Inc., San Francisco, CA (US)

(72) Inventor: Anthony Johnson, Lehi, UT (US)

(21) Appl. No.: 18/808,771

(22) Filed: Aug. 19, 2024

(51) Int. Cl. G06F 30/15

(52) U.S. Cl. CPC G06F 30/15

(57) ABSTRACT

Methods, systems, and apparatus, including medium-encoded computer program products include: obtaining first computer data comprising a simulation space including a grid of nodes; obtaining second computer data for two or more mobile entities, wherein the second computer data of each mobile entity includes a speed value and a deceleration value; and performing a discrete event travel simulation of the mobile entities in the simulation space. Each mobile entity moves along a respective path on the grid of nodes while avoiding collisions with the other mobile entities. Performing the discrete event travel simulation includes updating an allocation iterator that identifies a next node to be allocated along the path at a next node allocation time and a trailing iterator that identifies a trailing node along the path. The next node allocation time corresponds to a trailing node arrival time of the mobile entity to the trailing node.

### BACKGROUND

This specification relates to travel operations of mobile entities. Travel operations of mobile entities can be simulated using a discrete-event approach on a spatial grid of nodes.

### SUMMARY

This specification relates to travel operations of mobile entities. Travel operations of mobile entities can be simulated using a discrete-event approach on a spatial grid. The simulation can take into account acceleration and/or deceleration of the mobile entities.

In general, one or more aspects of the subject matter described in this specification can be embodied in one or more methods (and also one or more non-transitory computer-readable mediums tangibly encoding a computer program operable to cause one or more processors to perform operations), including: obtaining first computer data including a simulation space including a grid of nodes; obtaining second computer data for two or more mobile entities, wherein the second computer data of each mobile entity includes a speed value and a deceleration value; and performing a discrete event travel simulation of the two or more mobile entities in the simulation space, wherein each mobile entity moves along a respective path on the grid of nodes while avoiding collisions with the other mobile entities, wherein performing the discrete event travel simulation includes, for a mobile entity of the two or more mobile entities, updating i) an allocation iterator that identifies a next node to be allocated along the path at a next node allocation time and ii) a trailing iterator that identifies a trailing node along the path, wherein the next node allocation time corresponds to a trailing node arrival time of the mobile entity to the trailing node.

One or more aspects of the subject matter described in this specification can also be embodied in one or more systems including one or more processors; and a computer-readable medium storing instructions that cause the one or more processors to perform operations including: obtaining first computer data including a simulation space including a grid of nodes; obtaining second computer data for two or more mobile entities, wherein the second computer data of each mobile entity includes a speed value and a deceleration value; and performing a discrete event travel simulation of the two or more mobile entities in the simulation space, wherein each mobile entity moves along a respective path on the grid of nodes while avoiding collisions with the other mobile entities, wherein performing the discrete event travel simulation includes, for a mobile entity of the two or more mobile entities, updating i) an allocation iterator that identifies a next node to be allocated along the path at a next node allocation time and ii) a trailing iterator that identifies a trailing node along the path, wherein the next node allocation time corresponds to a trailing node arrival time of the mobile entity to the trailing node.

These and other aspects can each, optionally, include one or more of the following features. Updating the allocation iterator can include identifying the next node to be allocated and determining a next node arrival time of the mobile entity to the next node, a next node speed of the mobile entity at the next node, a next node stop distance of the mobile entity at the next node, and the next node allocation time, wherein the next node stop distance corresponds to a distance at which the mobile entity would stop when travelling at the deceleration value. Updating the trailing iterator can include identifying a node after the trailing node along the path; retrieving a stop distance of the mobile entity at the node after the trailing node; and updating the trailing iterator to the node after the trailing node when the stop distance at the node after the trailing node is less than a distance between the node after the trailing node and a node prior to the next node along the path. The second computer data of each mobile entity can further include an acceleration value. The next node speed can be determined using the acceleration value and the speed value. An event can be generated for the mobile entity at the next node allocation time. An event can be generated at the next node allocation time when it is determined that the next node to be allocated cannot be allocated to the mobile entity.

Particular embodiments of the subject matter described in this specification can be implemented to realize one or more of the following advantages. Acceleration and/or deceleration (i.e., positive and/or negative acceleration) can be taken into account in an efficient manner to provide more accurate time estimates of the travel operations for the mobile entity. The time needed for a mobile entity to accelerate to a target speed and/or the time needed for the mobile entity to decelerate to a stop can be efficiently tracked and taken into account using two iterators, i.e., an allocation iterator that tracks the next node that is to be allocated to the mobile entity and a trailing iterator that tracks a node where the mobile entity should start decelerating to a stop when allocation fails. With this technique, travel operations can be simulated more accurately while still maintaining a high degree of scalability in simulation run speed. Run speed in discrete event simulation (DES) systems can be improved by improving data structure access time and/or reducing the creation and consequent sorting, execution, and removal of events from the event queue. The systems and techniques described herein can be used for planning and/or controlling travel operations of mobile entities with collision avoidance taking into account acceleration and/or deceleration of the mobile entities. For example, the systems and techniques can be used for, e.g., path planning, scheduling of operations, and/or generation of control instructions for mobile entities. Further, the system and techniques described here can also be used to analyze and improve the design of an environment where travel operations take place.

The details of one or more embodiments of the subject matter described in this specification are set forth in the accompanying drawings and the description below. Other features, aspects, and advantages of the invention will become apparent from the description, the drawings, and the claims.

### BRIEF DESCRIPTION OF THE DRAWINGS

FIG. 1 shows an example of a system usable to facilitate simulation, planning, and/or control of travel operations of mobile entities.

FIG. 2 is a flowchart of a grid-based discrete-event travel simulation with deceleration.

FIG. 3 is a flowchart of a method for updating an allocation iterator in a grid-based discrete-event travel simulation.

FIG. 4 is a flowchart of a method for updating a trailing iterator in a grid-based discrete-event travel simulation.

FIGS. 5A-5E show examples of allocation planning for travel operations with acceleration and deceleration using a trailing iterator and an allocation iterator.

FIG. 6 is a schematic diagram of a data processing system including a data processing apparatus, which can be programmed as a client or as a server, and implement the techniques described in this document.

Like reference numbers and designations in the various drawings indicate like elements.

### DETAILED DESCRIPTION

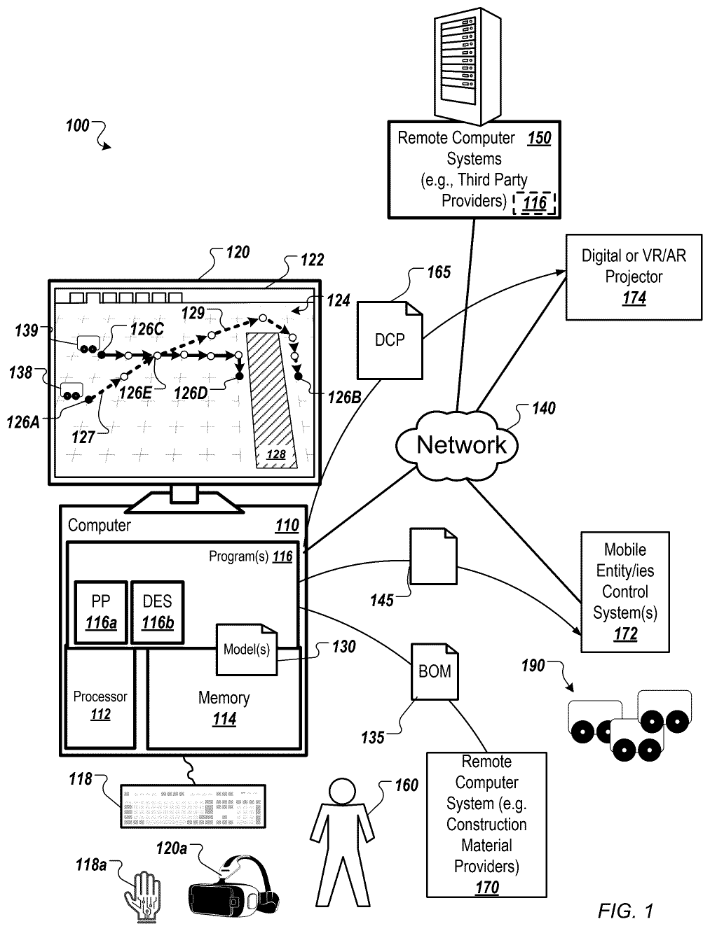

FIG. 1 shows an example of a system 100 usable to facilitate simulation, planning, and/or control of travel operations of mobile entities. For example, the mobile entities can be mobile robots, such as unmanned ground vehicles (UGVs), unmanned aerial vehicles (UAVs), unmanned surface vehicles (USVs), unmanned underwater vehicles (UUVs), etc.

A computer 110 includes a processor 112 and a memory 114. The computer 110 can be connected to a network 140, which can be a private network, a public network, a virtual private network, etc. The processor 112 can be one or more hardware processors, which can each include multiple processor cores. The memory 114 can include both volatile and non-volatile memory, such as Random Access Memory (RAM) and Flash RAM. The computer 110 can include various types of computer storage media and devices, which can include the memory 114, to store instructions of programs that run on the processor 112, including program(s) 116. Program(s) 116 can be computer aided design (CAD) and/or simulation programs and can include a path planning (PP) program 116a and a discrete-event simulation (DES) program 116b, such as a discrete-event simulation program for simulating travel operations as described herein.

As used herein, CAD refers to any suitable program used to design systems of interacting physical structures, machines, and/or devices. Program(s) 116 can include AEC (Architecture, Engineering and Construction) program(s), business and/or manufacturing system modelling program(s), etc. The program(s) 116 can model/build, analyze and/or optimize physical systems (with corresponding visualization of each physical system and activities therein) using three-dimensional (3D) and/or two-dimensional (2D) computer models and discrete event simulation. The program(s) 116 can run locally on computer 110, remotely on a computer of one or more remote computer systems 150 (e.g., one or more third party providers' one or more server systems accessible by the computer 110 via the network 140) or both locally and remotely. Thus, program(s) 116 can be two or more programs that operate cooperatively on two or more separate computer processors in that one or more programs 116 operating locally at computer 110 can offload processing operations (e.g., geometry generation and/or physical simulation operations) “to the cloud” by having one or more programs 116 on one or more computers 150 perform the offloaded processing operations. In some examples, some or all of the operations performed by PP program 116A and/or DES program 116B can be run in the cloud. In some examples, geometry generation operations can be run by one or more programs in the cloud and not in a geometry representation modeler (e.g., B-Rep modeler) that runs on the local computer. Moreover, in some implementations, the geometry generation program(s) can be run in the cloud from an Application Program Interface (API) that is called by a program, without user input through a graphical user interface.

The program(s) 116 can present a user interface (UI) 122 on a display device 120 of computer 110, which can be operated using one or more input devices 118 of the computer 110 (e.g., keyboard and mouse). Note that while shown as separate devices in FIG. 1, the display device 120 and/or input devices 118 can also be integrated with each other and/or with the computer 110, such as in a tablet computer (e.g., a touch screen can be an input/output device 118, 120). Moreover, the computer 110 can include or be part of a virtual reality (VR) and/or augmented reality (AR) system. For example, the input/output devices 118, and 120 can include VR/AR input controllers, gloves, or other hand manipulating tools 118a, and/or a VR/AR headset 120a. In some instances, the input/output devices can include hand-tracking devices that are based on sensors that track movement and recreate interaction as if performed with a physical input device. In some examples, VR and/or AR devices can be standalone devices that may not need to be connected to the computer 110. The VR and/or AR devices can be standalone devices that have processing capabilities and/or an integrated computer such as the computer 110, for example, with input/output hardware components such as controllers, sensors, detectors, etc.

In any case, a user 160 can interact with the program(s) 116 to generate and/or modify a simulation space 124 representing computer model(s) of a physical system, which can be stored in computer model document(s) 130. In the example of FIG. 1, the simulation space 124 includes a grid of nodes such as a nodes 126A, 126B, 126C, 126D, 126E where travel operations of one or more mobile entities 138, 139 can be simulated. The grid of nodes can be a regular grid with cells of uniform size, such as a hexagonal grid or a square grid (as shown). In some examples, the grid is an irregular grid with cells of variable size and/or shape. In some examples, the grid of nodes can be a three-dimensional grid of nodes.

A user 160 or a program can define origin nodes 126A, 126C and destination nodes 126B, 126D for one or more mobile entities 138, 139. In some instances, PP program 116A can be used to plan a trajectory and/or path for one or more mobile entities 138, 139. PP program 116A can use a guided path-finding algorithm such as A* algorithm (or other path-finding algorithms such as e.g., Dijkstra algorithm) to find the shortest path between an origin node 126A, 126C and a destination node 126B, 126D. Then, a program such as DES program 116B can be used to simulate travelling. For example, DES program 116b can be used to perform a discrete-event simulation of mobile entity 138 travelling from origin node 126A to destination node 126B and/or mobile entity 139 travelling from origin node 126C to destination node 126D, each one following a respective trajectory and/or path determined by PP program 116A.

In some examples, mobile entities can travel between nodes that are vertically or horizontally adjacent. In other words, entities can only travel in four directions: up, down, left, or right. In some examples, entities are allowed to travel diagonally. When entities would otherwise travel horizontally and then vertically or vice versa, they can be allowed to shorten travel by traveling along a diagonal such as diagonal 127. This allows entities to travel in up to eight directions instead of only four directions. In some examples, entities are allowed to travel along “deep diagonals,” such as deep diagonal 129, traversing diagonally two grid nodes horizontally and one grid node vertically, or vice versa. This allows entities to travel in up to sixteen directions, instead of only eight directions.

To avoid collisions, each node of the grid of nodes can be occupied by a single mobile entity at a time as they traverse the grid following their respective paths. The user 160 can interact with the program(s) 116 to define a layout of an environment in the simulation space 124. For example, the user 160 can define no-entry regions 128 such as walls or other obstacles where mobile entities cannot enter when traversing the simulation space. In some instances, the no-entry regions 128 are defined by the computer model of the physical system itself, where the program(s) 116 recognize which portions of the computer model constitute walls or other obstacles where mobile entities cannot enter.

PP program 116a can be used to plan a trajectory and/or a path between origin nodes 126A, 126C and destination nodes 126B, 126D taking into account any no-entry regions such as no-entry region 128. DES program 116b can schedule events of a discrete-event simulation of motion of mobile entity 138 from node 126A to node 126B and/or mobile entity 139 from node 126C to node 126D according to the planned trajectory and/or path, and respecting node-level exclusion to avoid collisions with each other and any other mobile entities. DES program 116b can take into account the acceleration and/or deceleration of the mobile entities to precisely and efficiently determine the time required for an entity to accelerate to a constant speed and/or the time needed for the mobile entity to decelerate to a stop to avoid a collision with another entity.

The results of the simulation can be used to modify the environment, e.g., to change the layout of the physical system in order to improve the travel operations of the mobile entities, e.g., to reduce travel distance and/or waiting times. Once the process has finished and the user 160 is satisfied with the layout, the simulation space can be used to generate or modify a computer model document 130 containing elements that will be used in constructing the layout of the physical system. For example, a BIM (Building Information Management) model can be generated or updated. The BIM model can be used to generate a bill of materials (BOM) 135 including elements that will be used for construction. The BOM can be stored, exported to an electronic document, and/or sent to a remote computer system 170, such as for one or more construction material providers. Note that an electronic document (which for brevity will simply be referred to as a document) can be a file but does not necessarily correspond to a file. A document may be stored in a portion of a file that holds other documents, in a single file dedicated to the document in question, or in multiple coordinated files. In addition, the user 160 can save or transmit the computer model(s) for later use.

In some examples, no physical manufacturing is involved. The systems and techniques described herein are applicable to any suitable 3D modelling software. Thus, in some examples, the program(s) 116 can be animation production program(s) that render the simulation space 124 to a document 165 of an appropriate format for visual display, such as by a digital projector 174 (e.g., a digital cinema package (DCP) 165 for movie distribution) or other high resolution display device. Other applications are also possible.

In some examples, the program(s) 116 can provide a document 145 including control instructions for control system(s) 172 of one or more mobile entities 190. The control instructions can include navigation instructions, and/or trajectory scheduling so that each mobile entity performs its respective operations following a path planned by e.g., PP program 116a according to the schedule determined by DES program 116b without colliding with the one or more other mobile entities.

A discrete-event simulation can simulate long times of large operations with many interacting entities much faster than, e.g., continuous time simulations like physics-based simulations. Discrete event simulation involves the execution of time-ordered events at specific points in simulated time that change the state of a model of an entity over time. This involves managing an event queue. Events are added and removed from this queue as the simulation runs, and events have to be executed in their correct simulation time order. Maintaining this time-ordering is non-trivial. Especially for large discrete-event simulation models that include many simultaneously running processes (e.g., simulations with around 1000 or more mobile entities), the size of the event queue can become very large (e.g., the event queue can have around 10000 or more events), and the mere operation of creating an event can be computationally intensive. Thus, maintaining run-speed for complex models can be a significant challenge. Discrete-event simulation algorithms should provide accurate simulations while requiring minimal creation, sorting, execution, and removal of events from the event queue.

When simulating travel operations, a speed/distance calculation can be used to calculate the time to travel between two locations, e.g., between two nodes of a grid of nodes. When an entity needs to travel from some origin location to some destination location, the distance between those locations (e.g., a straight-line distance calculation) can be determined and used to determine the time needed to travel to the destination. In other words, in a discrete-event simulation, an event will fire at the time when an entity needs to start traveling to a next destination. At that point, the simulation can determine the time needed to travel to the destination, e.g., by making a distance/speed calculation (travelTime=distance/speed.) Then, a new event can be created to fire at the time point (currentTime+travelTime) when the entity will arrive at the destination.

In grid-based settings, a path-finding algorithm can be used to move an entity between locations on a grid of nodes. In some examples, when an entity (e.g., entity 138) plans a travel operation from an origin node (e.g., node 126A) to a destination node (e.g., node 126B), a path to the destination can first be resolved, and then the entity can travel the pre-planned path using an event-based approach. Resolving the path to the destination involves finding a sequence of grid nodes to the destination using a path-finding algorithm, e.g., a guided path-finding algorithm such as A*. Then, the time to travel this path can be calculated based on a speed of the entity and the distance between nodes. Future events required to move the entity along the path from the origin to the destination can then be created and executed.

In a scenario in which interactions between multiple entities 138, 139 can be ignored, the most efficient method for performing a travel operation would be to calculate a total travel distance over the grid-based path from origin to destination and create a single event at the time it takes for the entity to get to the destination along the grid-based path. Although the path-finding algorithm is non-trivial, the discrete-event simulation requires a single event creation.

However, in most discrete-event simulation scenarios, interactions between multiple entities are important to simulating valid travel operations. High traffic regions create slowdowns that cause longer travel times, which are important for performing a valid simulation analysis of a system.

Discrete-event simulations can use allocation schemes on the grid of nodes to avoid collisions between entities or, in other words, to enforce space-based mutual exclusion of entities. To implement space-based mutual exclusion of entities at node-level, each node in the grid can only be allocated to one entity at a time and an entity cannot travel to a grid node until it has allocated that grid node. This keeps entities from colliding with each other through spatial mutual exclusion since it prevents entities from being on the same grid node at the same time.

In some examples, an allocation scheme can be implemented that fires an event every time a node needs to be allocated. First, the grid-based path from an origin node to a destination node can be calculated. Then, while the entity's current node is not the destination grid node, the entity tries to allocate the next node in the path, waiting at the current node until the next node can be allocated. To travel to the next node, the time to travel to the next node can be calculated, e.g., as distance/speed. The current node can then be deallocated (or an event to deallocate it with some offset time or distance required to clear the node can be created.) An event is created for the arrival time at the next node. When the arrival event executes, the entity's current node is updated to the next node.

In this type of allocation scheme, an event is fired every time a grid node needs to be allocated. If the entity cannot allocate the next node immediately, it will stop at its current node until it can allocate it. An event is created and executed on arrival at every grid node. Especially when grids are sparsely populated by entities, most of the time an entity will immediately allocate the next node. In sparsely-populated grids, most of the time an entity could have travelled most of the time without allocations, thus avoiding unnecessary intermediate event generation.

In some implementations, an allocation scheme based on allocation scheduling is provided. This allocation scheme can be more event-efficient, especially for grids that are sparsely populated. After path-finding is finished, an entity can “look ahead” through the planned path, calculating when it will arrive at each node based on its speed and inter-node distances. Then the entity can attempt to schedule allocation of each node along the path. This involves trying to allocate the node for a certain time slot. A grid node structure can track which entities are going to allocate which node at which times in the future. As long as there are no time collisions between the allocations (i.e., no allocations of different entities on the same grid node overlapping in time), the entity can schedule all the allocations for its entire path and create a single event for the arrival at the destination. On the other hand, if the allocation scheduling loop finds a time collision, the entity will create an event for when the time collision happens, and then stop just before the collision node and wait until it can allocate the node.

This allocation scheme can be more event-efficient than the event-heavy algorithm described above. Especially in sparsely populated grids the number of events that must be created can be orders of magnitude smaller. Events are only created when an allocation fails (i.e., when an entity must wait for another entity to deallocate a node) or when the entity finishes the travel operation.

In any case, standard grid-based travel simulation algorithms usually assume that entities instantaneously accelerate from a stop to a target speed (e.g., a maximum speed or a cruising speed) when they have to move to their next allocated node. Likewise, standard grid-based travel simulations usually assume that they also decelerate instantaneously from their target speed to a stop. However, accurate simulations might require that proper accelerations and decelerations are represented. When an entity starts to travel, it usually needs to accelerate from being stopped up to a target speed. When the entity stops, it should be able to smoothly decelerate from its target speed down to being stopped. Accelerating to the target speed and/or decelerating to being stopped increases the total time that it takes to travel to a destination. This difference becomes more significant the more the entity must frequently stop to avoid collisions with other entities during travel. When acceleration and/or deceleration are not taken into account in travel simulations, simulated travel time might be lower than actual travel times. Simulating actual acceleration and deceleration can improve the accuracy of travel simulations significantly.

In both of the allocation schemes described above, the entity first travels to a node and then attempts to allocate the next node. If the entity cannot allocate the next node, it instantaneously stops at the previous node. In order to simulate deceleration, the techniques described herein give the entity more time and space to decelerate when it cannot allocate a next node. This is done by moving the allocation time (i.e., the start time of the allocation of the node) to an earlier time point in order to be able to decelerate to a stop when the entity cannot allocate the node. Specifically, the point in time when the entity attempts to allocate a node can be, at the latest, the point in time when, if the entity fails to allocate the node, the entity still has enough space to decelerate to a stop at the grid node previous to the node it failed to allocate.

Entities with low deceleration values must travel long stretches to decelerate to a stop. Therefore, they must allocate upcoming nodes in the path earlier than entities with high deceleration values. Instead of allocating one node ahead at a time, entities with small deceleration values can allocate multiple grid nodes that can be far ahead of their current position. To efficiently implement an allocation scheme with deceleration, the techniques described herein keep an allocation iterator that tracks the grid node whose allocation is being requested as well as a trailing iterator that tracks the grid node where deceleration should begin.

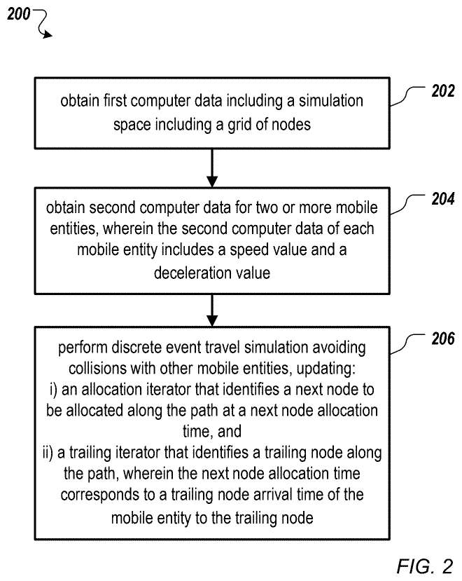

FIG. 2 is a flowchart of a grid-based discrete-event travel simulation 200 with deceleration. At 202, first computer data including a simulation space including a grid of nodes is obtained. For example, a simulation space such as simulation space 124 as shown in FIG. 1 can be obtained. At 204, second computer data for mobile entities is obtained. For example, the second computer data can be computer data for two or more mobile entities such as mobile entities 138, 139 as shown in FIG. 1. The second computer data of each mobile entity can include a speed value and a deceleration value. The speed value can be a target speed value, such as a maximum speed or a cruising speed. The deceleration value is a negative acceleration value corresponding to the deceleration of the entity when it is traveling at the speed value and decelerates to a stop. Further, an acceleration value can be obtained 204 and then used, as described herein; and in some implementations, a single acceleration value is obtained 204, a positive version of this value is used for acceleration, and a negative version of this value is used for deceleration (when a mobile entity accelerates and decelerates at the same rate).

At 206, a discrete event travel simulation of the mobile entities (such as two or more mobile entities 138, 139) in the simulation space is performed. Each mobile entity moves along a respective path on the grid of nodes while avoiding collisions with the other mobile entities. The path can be a path between an origin node and a destination node. The path can be a shortest path that is determined with a path-finding algorithm. Performing the discrete event travel simulation includes updating i) an allocation iterator that identifies a next node to be allocated along the path at a next node allocation time and ii) a trailing iterator that identifies a trailing node along the path. The next node allocation time corresponds to a trailing node arrival time of the mobile entity to the trailing node.

The distance required to decelerate to a stop can be quantified. Given a speed v and deceleration a⁻, the distance dₛₜₒₚ that must be traveled to decelerate to a stop can be calculated as dₛₜₒₚ=0.5*v²/a⁻.

Additionally, an acceleration a⁺ can be taken into account. The speed of the entity as it accelerates from being stopped to traveling at full speed can thus be tracked. The acceleration duration may span the traversal of multiple grid nodes. The speed as it increases at each grid node arrival can be tracked. For a time window during which the entity is accelerating with an acceleration a⁺ from an initial speed v₀ to some subsequent velocity v₁, the distance d traveled over that time window is calculated as d=0.5*(v₁+v₀)*(v₁−v₀)/a⁺. Alternatively, if the distance d in the above formula is known (e.g., the distance between grid nodes, which is a known value), the velocity v₁ of the entity when arriving at distance d can be determined as v₁=(2*d*a⁺+v₀²)^{1/2}. Further, the time t₁ at which the entity will arrive at distance d, given that the entity starts moving at time t₀ at speed v₀ and accelerates to speed v₁, is given by t₁=t₀+d/[0.5(v₀+v₁)].

Using these equations, the speed and time at which the entity arrives at each grid node can be tracked. Also, the distance it will take to stop after that point, given the arrival speed can be determined. These calculations can be used to determine allocation times taking into account acceleration and/or deceleration of the mobile entity.

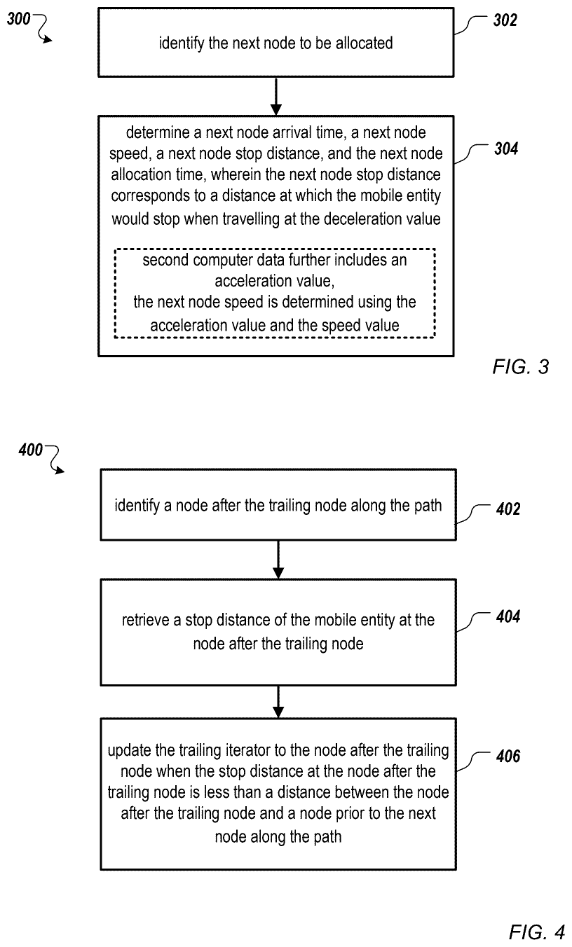

FIG. 3 is a flowchart of a method 300 for updating an allocation iterator in a grid-based discrete-event travel simulation. The allocation iterator is the primary path traversal iterator and is incremented on each path traversal loop iteration, i.e., it identifies the next node to be allocated along the path. For that node, the time and speed at which the entity will arrive (if unimpeded) can be calculated using the formulas described above. The distance it would take to decelerate to a stop from that node can also be calculated using the formulas described above.

For example, at 302, the next node to be allocated is identified. At 304, a next node arrival time of the mobile entity to the next node, a next node speed of the mobile entity at the next node, a next node stop distance of the mobile entity at the next node, and the next node allocation time, wherein the next node stop distance corresponds to a distance at which the mobile entity would stop when travelling at the deceleration value. The second computer data of each mobile entity can further include an acceleration value. The next node speed can be determined using the acceleration value and the speed value.

FIG. 4 is a flowchart of a method 400 for updating a trailing iterator in a grid-based discrete-event travel simulation. The trailing iterator lags behind the allocation iterator. It is used to determine the allocation time of each allocation referenced by the allocation iterator. This iterator can be incremented when such an increment would result in the stop distance still being less than the distance from the trailing iterator's grid node to the previous node of the allocation iterator.

For example, at 402, a node after the trailing node along the path can be identified. At 404, a stop distance of the mobile entity at the node after the trailing node can be retrieved. At 406, the trailing iterator is updated to the node after the trailing node when the stop distance at the node after the trailing node is less than a distance between the node after the trailing node and a node prior to the next node along the path. Otherwise, the trailing iterator is not updated.

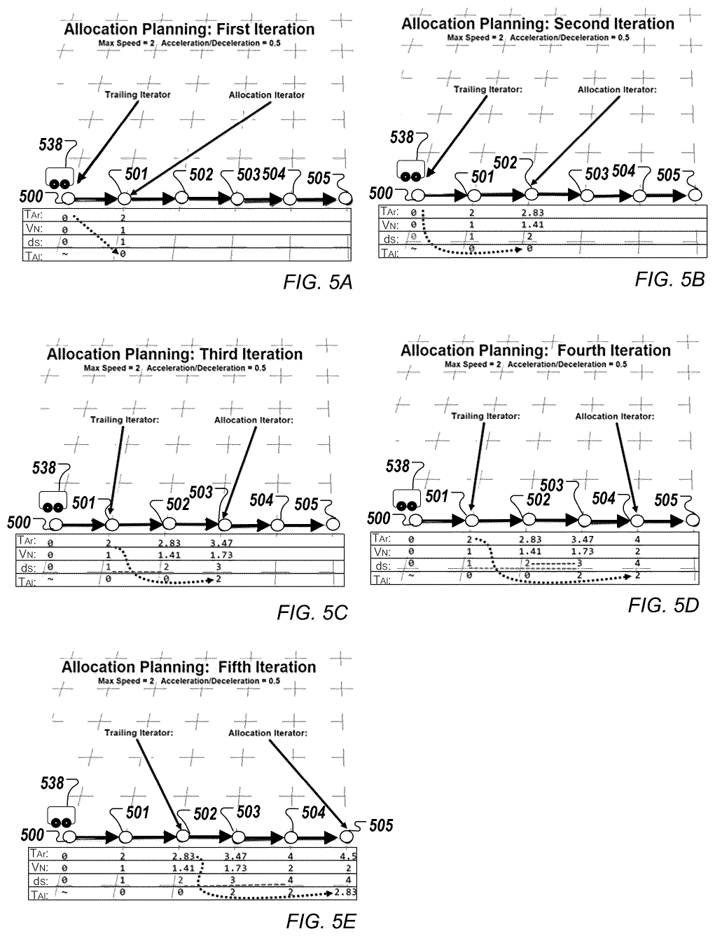

FIGS. 5A-5E show examples of allocation planning for travel operations with acceleration and deceleration using a trailing iterator and an allocation iterator. Before performing allocation planning, a path from an origin node to a destination node can be resolved as a sequence of grid node visits. In the examples of FIGS. 5A-5E, a path for mobile entity 538 to travel from node 500 to node 505 traversing nodes 501, 502, 503, 504 is shown. In this case, allocation planning in order to perform the discrete-event travel simulation takes into account that the distance between grid nodes is d=1, the target speed (or maximum speed) for mobile entity 538 is 2, and its acceleration and deceleration are a⁺=a⁻=0.5. Dimensionless units are used for all quantities, including time.

FIG. 5A shows the first iteration of allocation planning. Initial values are set for origin node 500. As shown in FIG. 5A, the trailing iterator is initially set to the entity's current node, i.e., origin node 500. The allocation iterator is set to the next node to be allocated along the path at a next allocation time, i.e., the first node to visit 501. The trailing iterator node's arrival time is set to the current simulation time, zero in this case. Assuming the entity starts at an initial velocity equal to zero, its stop distance is stored as zero.

On each iteration, using the equations above, at each grid node visit (i.e., at the next node to be allocated) the speed v_{N} at which the entity will be traveling when arriving at that node, the time the entity will arrive T_{Ar} at that node, and the stop distance dₛ based on that arrival speed v_{N} can be determined. The trailing iterator can be incremented as long as doing so results in the trailing iterator identifying a node along the path whose stop distance dₛ is still less than the distance from the updated trailing iterator's node to the allocation iterator's previous node. The allocation time of the allocation iterator is then set to the arrival time of the node identified by the trailing iterator. The deallocation time of the grid node visit can be set as the point at which the entity leaves that node, which can be the same as the arrival time, optionally offset by some user-defined time or travel distance.

As shown in FIG. 5A, in the first iteration the trailing iterator is initially set to the entity's current node, i.e., origin node 500. The allocation iterator is set to the next node to be allocated along the path at a next allocation time, i.e., the first node to visit 501. The arrival time T_{Ar} of the first node 501 can be calculated making use of the formulas described above as the time it takes for entity 538 to travel to that first node 501, namely T_{Ar}=2 time units. The speed of entity 538 when it reaches the first node 501 can also be calculated making use of the formulas described above to be V_{N}=1. The distance that the mobile entity would need to cover to decelerate to a stop after the first node 501 can be calculated to be ds=1. The allocation time T_{Al} for the first node 501 is set to the arrival time of the trailing node identified by the trailing iterator, in this case origin node 500, i.e., T_{Al}=0.

FIG. 5B shows the second iteration of allocation planning. On the second iteration, the allocation iterator is updated to the next node, i.e., the second node to visit 502. Its arrival time T_{Ar}=2.83, speed V_{N}=1.41, and stop distance ds=2 are calculated making use of the formulas described above. Then, the algorithm checks if the trailing iterator is to be incremented to the node after the trailing node, i.e., updated to identify first node 501 instead of origin node 500. The stop distance for first node 501 is dₛ=1. This value is greater than the distance between the node after the trailing node (i.e., first node 501) and the allocation iterator's previous node (i.e., first node 501), since the distance between first node 501 and itself is 0. Consequently, the trailing iterator is not incremented. The allocation time for the second node 502 is set to T_{Al}=0 (i.e., the arrival time of the trailing node identified by the trailing iterator).

FIG. 5C shows the third iteration of allocation planning. On the third iteration, the allocation iterator is updated to the next node, i.e., the third node to visit 503. Its arrival time T_{Ar}=3.47, speed V_{N}=1.73, and stop distance ds=3 are calculated making use of the formulas described above. Then, the algorithm checks if the trailing iterator is to be incremented to the node after the trailing node, i.e., updated to identify first node 501 instead of origin node 500. The stop distance for first node 501 is dₛ=1. This value is not greater than the distance between the node after the trailing node (i.e., first node 501) and the allocation iterator's previous node (i.e., second node 502) since the distance between second node 502 and first node 501 is 1. Consequently, the trailing iterator can be incremented to first node 501. The allocation time for the third node 503 is set to T_{Al}=2 (i.e., the arrival time of the trailing node identified by the trailing iterator).

FIGS. 5D and 5E show the fourth and fifth iterations of allocation planning, respectively, using the formulas described above to determine arrival time, speed, stop distance, and allocation time for the next node to be allocated and using the same logic to update the allocation iterator and trailing iterator. On the fourth iteration, the allocation iterator is updated to the next node, i.e., the fourth node to visit 504. Its arrival time T_{Ar}=4, speed V_{N}=2, and stop distance ds=4 are calculated making use of the formulas described above. Then, the algorithm checks if the trailing iterator is to be incremented to the node after the trailing node, i.e., updated to identify second node 502 instead of first node 501. The stop distance for second node 502 is dₛ=2. This value is greater than the distance between the node after the trailing node (i.e., second node 502) and the allocation iterator's previous node (i.e., third node 503) since the distance between third node 503 and second node 502 is 1. Consequently, the trailing iterator cannot be incremented to second node 502. The allocation time for the fourth node 504 is set to T_{Al}=2 (i.e., the arrival time of the trailing node identified by the trailing iterator). On the fifth iteration, the allocation iterator is updated to the next node, i.e., the fifth node to visit 505. Its arrival time T_{Ar}=4.5, speed V_{N}=2, and stop distance ds=4 are calculated making use of the formulas described above. Then, the algorithm checks if the trailing iterator is to be incremented to the node after the trailing node, i.e., updated to identify second node 502 instead of first node 501. The stop distance for second node 502 is dₛ=2. This value is not greater than the distance between the node after the trailing node (i.e., second node 502) and the allocation iterator's previous node (i.e., fourth node 504) since the distance between fourth node 504 and second node 502 is 2. Consequently, the trailing iterator can be incremented to second node 502. The allocation time for the fifth node 505 is set to T_{Al}=2.83 (i.e., the arrival time of the trailing node identified by the trailing iterator).

A node's allocation time (i.e., the start time of the allocation of that node) does not need to be at the exact same time as an arrival time of the entity at a node (e.g., the arrival time of the trailing iterator node). In some cases, a node's allocation time can correspond to an intermediate time. In some examples, for simplicity, the allocation time is assumed to be the arrival time. In other examples, if the stop distance associated with a node arrival is strictly less than the distance from the trailing iterator node to the allocation iterator's previous node, the formulas above for speed and distance can be used to determine an additional time before the allocation iterator's node needs to be allocated. For example, the formulas above can be used to generate a motion profile for the entity representing the velocity, acceleration, and/or distance travelled through time (e.g., the time periods when the entity is accelerating, travelling at its target speed, or decelerating). The motion profile can be interrogated to determine the exact time at which deceleration starts. This time can be added as an additional time to the arrival time of the trailing node to determine the node's allocation time. In any case, the trailing iterator can serve as a reference point of the last visited node in the path for quickly resolving where the entity is in its path when the allocation fails.

If the allocation scheduling loop finds a time collision with a second mobile entity at the next node to be allocated. A time collision occurs if there is an overlap between the time period during which the first mobile entity and the second mobile entity want to allocate the next node. If there is a time collision, one of the entities will not be able to allocate the next node at its allocation time. In particular, if the allocation time for the next node for the first mobile entity starts later than the allocation time for the next node for the second mobile entity, the next node will be allocated to the second entity and vice versa. If the discrete-event simulation is implemented as a schedule-based allocation scheme, as described above, when the next node to be allocated cannot be allocated by the first mobile entity, an event is generated at the time where the next node should have been allocated. The first mobile entity decelerates to a stop at the furthest successfully allocated node and waits until it can allocate the next node.

If the discrete-event simulation is implemented as an event-heavy allocation scheme, an event is generated at each allocation time of each next node to be allocated. Then, an attempt to allocate the next node is made. If it fails, the first entity decelerates to stop at the furthest successfully allocated node.

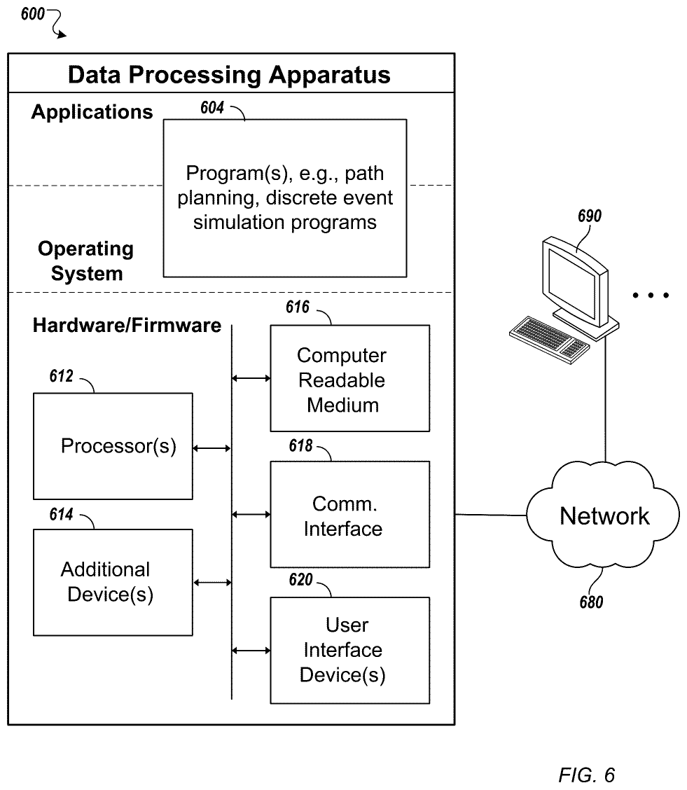

FIG. 6 is a schematic diagram of a data processing system including a data processing apparatus 600, which can be programmed as a client or as a server. The data processing apparatus 600 is connected with one or more computers 690 through a network 680. While only one computer is shown in FIG. 6 as the data processing apparatus 600, multiple computers can be used. The data processing apparatus 600 includes various software modules, which can be distributed between an applications layer and an operating system. These can include executable and/or interpretable software programs or libraries, including tools and services of one or more programs 604 that implement trajectory and/or path planning, and/or discrete-event simulations, as described above. Thus, the program(s) 604 can be program(s) 116 (such as path planning program(s) 116a and discrete event simulation program(s) 116b) and can implement one or more grid-based discrete-event simulation of travel operations with one or more exclusion regions. Further, the program(s) 604 can potentially implement one or more of generation of control instructions (path navigation and/or trajectory scheduling) for mobile entities, control of operations of mobile entities, room layout design and/or improvement, or BOM generation. The number of software modules used can vary from one implementation to another. Moreover, the software modules can be distributed on one or more data processing apparatus connected by one or more computer networks or other suitable communication networks.

The data processing apparatus 600 also includes hardware or firmware devices including one or more processors 612, one or more additional devices 614, a computer readable medium 616, a communication interface 618, and one or more user interface devices 620. Each processor 612 is capable of processing instructions for execution within the data processing apparatus 600. In some examples, the processor 612 is a single or multi-threaded processor. Each processor 612 is capable of processing instructions stored on the computer readable medium 616 or on a storage device such as one of the additional devices 614. The data processing apparatus 600 uses the communication interface 620 to communicate with one or more computers 690, for example, over the network 680. Examples of user interface devices 620 include a display, a camera, a speaker, a microphone, a tactile feedback device, a keyboard, a mouse, and VR and/or AR equipment. The data processing apparatus 600 can store instructions that implement operations associated with the program(s) described above, for example, on the computer readable medium 616 or one or more additional devices 614, for example, one or more of a hard disk device, an optical disk device, a tape device, and a solid state memory device.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented using one or more modules of computer program instructions encoded on a non-transitory computer-readable medium for execution by, or to control the operation of, data processing apparatus. The computer-readable medium can be a manufactured product, such as hard drive in a computer system or an optical disc sold through retail channels, or an embedded system. The computer-readable medium can be acquired separately and later encoded with the one or more modules of computer program instructions, e.g., after delivery of the one or more modules of computer program instructions over a wired or wireless network. The computer-readable medium can be a machine-readable storage device, a machine-readable storage substrate, a memory device, or a combination of one or more of them.

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, a runtime environment, or a combination of one or more of them. In addition, the apparatus can employ various different computing model infrastructures, such as web services, distributed computing and grid computing infrastructures.

A computer program (also known as a program, software, software application, script, or code) can be written in any suitable form of programming language, including compiled or interpreted languages, declarative or procedural languages, and it can be deployed in any suitable form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM (Erasable Programmable Read-Only Memory), EEPROM (Electrically Erasable Programmable Read-Only Memory), and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., an LCD (liquid crystal display) display device, an OLED (organic light emitting diode) display device, or another monitor, for displaying information to the user, and a keyboard and a pointing device, e.g., a mouse or a trackball, by which the user can provide input to the computer. Other kinds of devices can be used to provide for interaction with a user as well; for example, feedback provided to the user can be any suitable form of sensory feedback, e.g., visual feedback, auditory feedback, or tactile feedback; and input from the user can be received in any suitable form, including acoustic, speech, or tactile input.

The computing system can include clients and servers. A client and server are generally remote from each other and typically interact through a communication network. The relationship of client and server arises by virtue of computer programs running on the respective computers and having a client-server relationship to each other. Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a browser user interface through which a user can interact with an implementation of the subject matter described is this specification, or any combination of one or more such back-end, middleware, or front-end components. The components of the system can be interconnected by any suitable form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

While this specification contains many implementation details, these should not be construed as limitations on the scope of what is being or may be claimed, but rather as descriptions of features specific to particular embodiments of the disclosed subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. In addition, actions recited in the claims can be performed in a different order and still achieve desirable results.

What is claimed is:

1. A method performed by a data processing apparatus, the method comprising:
obtaining first computer data comprising a simulation space comprising a grid of nodes;
obtaining second computer data for two or more mobile entities, wherein the second computer data of each mobile entity comprises a speed value and a deceleration value; and
performing a discrete event travel simulation of the two or more mobile entities in the simulation space, wherein each mobile entity moves along a respective path on the grid of nodes while avoiding collisions with the other mobile entities, wherein performing the discrete event travel simulation comprises, for a mobile entity of the two or more mobile entities, updating i) an allocation iterator that identifies a next node to be allocated along the path at a next node allocation time and ii) a trailing iterator that identifies a trailing node along the path, wherein the next node allocation time corresponds to a trailing node arrival time of the mobile entity to the trailing node.

2. The method of claim 1, wherein updating the allocation iterator comprises:
identifying the next node to be allocated; and
determining a next node arrival time of the mobile entity to the next node, a next node speed of the mobile entity at the next node, a next node stop distance of the mobile entity at the next node, and the next node allocation time, wherein the next node stop distance corresponds to a distance at which the mobile entity would stop when travelling at the deceleration value.

3. The method of claim 2, wherein updating the trailing iterator comprises:
identifying a node after the trailing node along the path;
retrieving a stop distance of the mobile entity at the node after the trailing node; and
updating the trailing iterator to the node after the trailing node when the stop distance at the node after the trailing node is less than a distance between the node after the trailing node and a node prior to the next node along the path.

4. The method of claim 2, wherein the second computer data of each mobile entity further comprises an acceleration value, wherein the next node speed is determined using the acceleration value and the speed value.

5. The method of claim 1, wherein an event is generated for the mobile entity at the next node allocation time.

6. The method of claim 1, wherein an event is generated at the next node allocation time when it is determined that the next node to be allocated cannot be allocated to the mobile entity.

7. A system comprising:
one or more processors; and
a computer-readable medium storing instructions which, when executed, cause the one or more processors to perform operations comprising:
obtaining first computer data comprising a simulation space comprising a grid of nodes;
obtaining second computer data for two or more mobile entities, wherein the second computer data of each mobile entity comprises a speed value and a deceleration value; and
performing a discrete event travel simulation of the two or more mobile entities in the simulation space, wherein each mobile entity moves along a respective path on the grid of nodes while avoiding collisions with the other mobile entities, wherein performing the discrete event travel simulation comprises, for a mobile entity of the two or more mobile entities, updating i) an allocation iterator that identifies a next node to be allocated along the path at a next node allocation time and ii) a trailing iterator that identifies a trailing node along the path, wherein the next node allocation time corresponds to a trailing node arrival time of the mobile entity to the trailing node.

8. The system of claim 7, wherein updating the allocation iterator comprises:
identifying the next node to be allocated; and
determining a next node arrival time of the mobile entity to the next node, a next node speed of the mobile entity at the next node, a next node stop distance of the mobile entity at the next node, and the next node allocation time, wherein the next node stop distance corresponds to a distance at which the mobile entity would stop when travelling at the deceleration value.

9. The system of claim 8, wherein updating the trailing iterator comprises:
identifying a node after the trailing node along the path;
retrieving a stop distance of the mobile entity at the node after the trailing node; and
updating the trailing iterator to the node after the trailing node when the stop distance at the node after the trailing node is less than a distance between the node after the trailing node and a node prior to the next node along the path.

10. The system of claim 8, wherein the second computer data of each mobile entity further comprises an acceleration value, wherein the next node speed is determined using the acceleration value and the speed value.

11. The system of claim 7, wherein an event is generated for the mobile entity at the next node allocation time.

12. The system of claim 7, wherein an event is generated at the next node allocation time when it is determined that the next node to be allocated cannot be allocated to the mobile entity.

13. A non-transitory computer-readable medium tangibly encoding a computer program operable to cause a processing system to perform operations comprising:
obtaining first computer data comprising a simulation space comprising a grid of nodes;
obtaining second computer data for two or more mobile entities, wherein the second computer data of each mobile entity comprises a speed value and a deceleration value; and
performing a discrete event travel simulation of the two or more mobile entities in the simulation space, wherein each mobile entity moves along a respective path on the grid of nodes while avoiding collisions with the other mobile entities, wherein performing the discrete event travel simulation comprises, for a mobile entity of the two or more mobile entities, updating i) an allocation iterator that identifies a next node to be allocated along the path at a next node allocation time and ii) a trailing iterator that identifies a trailing node along the path, wherein the next node allocation time corresponds to a trailing node arrival time of the mobile entity to the trailing node.

14. The computer-readable medium of claim 13, wherein updating the allocation iterator comprises:
identifying the next node to be allocated; and
determining a next node arrival time of the mobile entity to the next node, a next node speed of the mobile entity at the next node, a next node stop distance of the mobile entity at the next node, and the next node allocation time, wherein the next node stop distance corresponds to a distance at which the mobile entity would stop when travelling at the deceleration value.

15. The computer-readable medium of claim 14, wherein updating the trailing iterator comprises:
identifying a node after the trailing node along the path;
retrieving a stop distance of the mobile entity at the node after the trailing node; and
updating the trailing iterator to the node after the trailing node when the stop distance at the node after the trailing node is less than a distance between the node after the trailing node and a node prior to the next node along the path.

16. The computer-readable medium of claim 14, wherein the second computer data of each mobile entity further comprises an acceleration value, wherein the next node speed is determined using the acceleration value and the speed value.

17. The computer-readable medium of claim 13, wherein an event is generated for the mobile entity at the next node allocation time.

18. The computer-readable medium of claim 13, wherein an event is generated at the next node allocation time when it is determined that the next node to be allocated cannot be allocated to the mobile entity.
